(19) United States
(12) Patent Application Publication
(10) Pub. No.: US 2025/0337175 A1
(43) Pub. Date: Oct. 30, 2025

(54) CAPACITOR MODULE WITH FLEXIBLE CONTACTS

(71) Applicant: Rivian IP Holdings, LLC, Irvine, CA (US)

(72) Inventors: Young DOO, La Palma, CA (US); Che Daniel SILKISS-HERO, Long Beach, CA (US); Juan LOPEZ, Wildomar, CA (US); Navin PILLAI, Carson, CA (US)

(21) Appl. No.: 18/651,622

(22) Filed: Apr. 30, 2024

(51) Int. Cl. H01R 4/02; H01G 4/38; H01R 43/02; H02M 1/00; H02M 7/00

(52) U.S. Cl. CPC H01R 4/029; H01G 4/38; H01R 43/0221; H01R 43/0263; H02M 1/0067; H02M 7/003

(57) ABSTRACT

Certain embodiments provide a capacitor module with flexible busbar contacts for a traction inverter system of an electric vehicle. The capacitor module may include a housing, capacitors, and capacitor busbar contacts coupled to the capacitors. Each capacitor busbar contact may include a flexible portion and a contact portion configured to be attached to a respective power inverter module busbar contact. The flexible portion and the contact portion are disposed outside the housing. The flexible portion is configured to bend to reduce or close an air gap between the contact portion and a respective power inverter module busbar contact when a force is applied to the contact portion prior to attachment. In some embodiments, the contact portion is laser welded to the respective power inverter module busbar contact, and a clamp applies the force to the contact portion prior to laser welding.

### INTRODUCTION

The present disclosure relates to electric vehicles (EVs). More particularly, the present disclosure relates to a capacitor module for an electric vehicle.

### SUMMARY

Embodiments of the present disclosure advantageously provide a capacitor module with flexible busbar contacts for a traction inverter system of an electric vehicle.

In certain embodiments, a capacitor module includes a housing, a plurality of capacitors, and a plurality of capacitor busbar contacts coupled to the capacitors. Each capacitor busbar contact includes a flexible portion and a contact portion configured to be attached to a respective power inverter module (PIM) busbar contact. The flexible portion and the contact portion are disposed outside the housing. The flexible portion is configured to bend under a force to reduce or close an air gap between the contact portion and the respective PIM busbar contact prior to attaching the contact portion to the respective PIM busbar contact. In some embodiments, the contact portion is laser welded to the respective PIM busbar contact, and a clamp applies the force to the contact portion prior to laser welding

In certain embodiments, a traction inverter system for an electric vehicle includes a plurality of PIMs and a capacitor module. Each PIM includes an inverter and a pair of busbar contacts. The capacitor module includes a housing, a plurality of capacitors, and a plurality of capacitor busbar contacts coupled to the capacitors. Each capacitor busbar contact includes a flexible portion, and a contact portion attached to a respective PIM busbar contact. The flexible portion and the contact portion are disposed outside the housing. The capacitor busbar contacts are arranged as pairs of capacitor busbar contacts, and each pair of capacitor busbar contacts is attached to the pair of busbar contacts on one of the PIMs. In some embodiments, the contact portion is laser welded to the respective PIM busbar contact.

### BRIEF DESCRIPTION OF THE DRAWINGS

FIG. 1 depicts a diagram of an example electric vehicle, in accordance with embodiments of the present disclosure.

FIGS. 2A, 2B, 2C, 2D present top, bottom, front, and rear views of an example traction inverter system (respectively), in accordance with embodiments of the present disclosure.

FIG. 3A presents a perspective sectional view through the traction inverter system, in accordance with embodiments of the present disclosure.

FIG. 3B presents a front sectional view through the traction inverter system, in accordance with embodiments of the present disclosure.

FIG. 4A presents a perspective view of an example capacitor module, in accordance with embodiments of the present disclosure.

FIG. 4B presents a partial sectional view through the capacitor module, in accordance with embodiments of the present disclosure.

FIGS. 5A, 5B present a clamping process prior to laser welding for the example capacitor module and an example power inverter module (PIM), in accordance with embodiments of the present disclosure.

### DETAILED DESCRIPTION

Generally, a DC link capacitor includes a bank of capacitors that stabilizes the DC voltage received from the battery to limit fluctuations when the inverters of the PIMs intermittently demand a large (or heavy) DC current. The DC link capacitor is coupled to the PIMs using busbar contacts, which are flat, rectangular conductive segments that are configured to be attached to one another using fasteners or certain welding techniques. The busbar contacts may be formed from a conductive material, such as copper, aluminum, etc.

For example, laser welding requires that the capacitor busbar contacts abut (or contact) the PIM busbar contacts without an air gap, which would reduce the strength of the laser weld. Unfortunately, part tolerances in the DC link capacitor module and the PIM may cause the formation of the air gap during laser welding with a concomitant reduction in the strength of the laser weld. Other welding techniques may also suffer from similar issues.

Embodiments of the present disclosure advantageously provide a capacitor module with flexible busbar contacts for a traction inverter system of an electric vehicle.

Each flexible capacitor busbar contact includes a flexible portion and a contact portion configured to be laser welded to a respective PIM busbar contact. The flexible portion and the contact portion are disposed outside of the housing of the capacitor module. The flexible portion is configured to bend to reduce or close an air gap between the contact portion and the respective PIM busbar contact when the contact portion is clamped to the respective PIM busbar contact prior to laser welding.

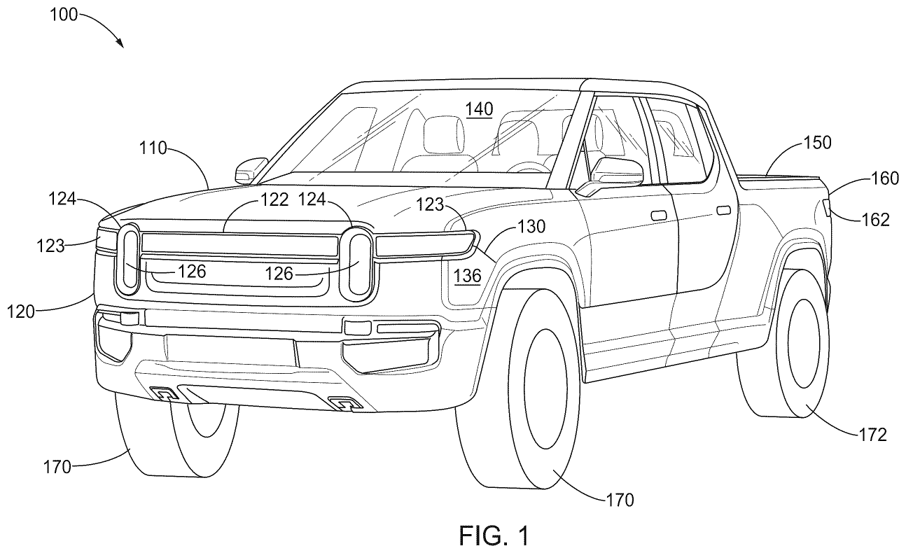

FIG. 1 depicts a diagram of an electric vehicle 100, in accordance with embodiments of the present disclosure.

Electric vehicle 100 includes, inter alia, a frame and body 110, an electrical power storage and distribution system, a propulsion system, a suspension system, a steering system, auxiliary and accessory systems (such as thermal management, lighting, wireless communications, navigation, etc.), etc.

Generally, body 110 may be directly or indirectly mounted to a frame (i.e., body-on-frame construction), or body 110 may be formed integrally with a frame (i.e., unibody construction). Body 110 includes, inter alia, front end 120, front light bar 122, front turn lights 123, stadium light ring 124, headlights 126, charging port 130 with charging port cover 136 concealing charging connector socket, driver/passenger compartment or cabin 140, bed 150, rear end 160 with rear tail lights 162, a rear light bar, etc. Electric vehicle 100 may be a pickup truck, a sport utility vehicle (SUV) in which bed 150 is replaced by an extension of cabin 140, or a sedan in which bed 150 is replaced by a trunk. In certain embodiments, electric vehicle may be an electric delivery vehicle, an electric cargo van, etc.

The propulsion system may include, inter alia, one or more electronic control units (ECUs), one or more electric drive unit (EDUs), front wheels 170, rear wheels 172, etc. The electrical power storage and distribution system may include, inter alia, one or more ECUs, a battery enclosure containing a battery pack including one or more batteries or battery modules (hereinafter “the battery”), a vehicle charging subsystem including charging port 130, high voltage (HV) cables connecting the battery to the EDUs, etc.

A single motor EDU may be used to drive front wheels 170 (front wheel drive) or rear wheels 172 (rear wheel drive). Additionally, a single motor EDU may be used to drive front wheels 170 and a single motor EDU may be used to drive rear wheels 172 (four wheel drive). A single motor EDU includes, inter alia, an AC electric motor, a gearbox, and a traction inverter system containing power electronics. The gearbox couples the AC motor to a common drive shaft for the front or rear wheels. The traction inverter system converts the DC power received from the battery to AC power to drive the AC electric motor. During regeneration, the traction inverter system converts the AC power generated by the AC motor into DC power to recharge the battery.

A dual motor EDU may be used to independently drive front wheels 170 (independent front wheel drive) or rear wheels 172 (independent rear wheel drive). Additionally a dual motor EDU may be used to independently drive both front wheels 170 and a dual motor EDU may be used to independently drive both rear wheels 172 (independent four wheel drive). A dual motor EDU includes, inter alia, two AC electric motors, two gearboxes, and a traction inverter system containing the power electronics. Each gearbox couples one AC electric motor to a dedicated drive shaft for one wheel. The traction inverter system converts the DC power received from the battery to AC power to drive each AC electric motor. During regeneration, the traction inverter system converts the AC power generated by the AC motors into DC power to recharge the battery.

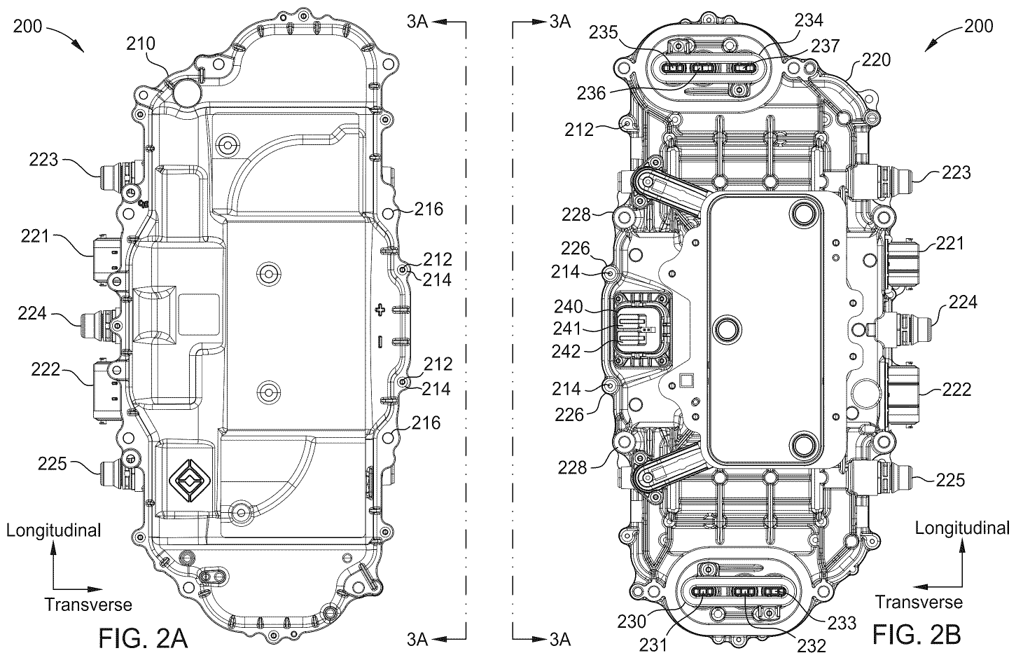

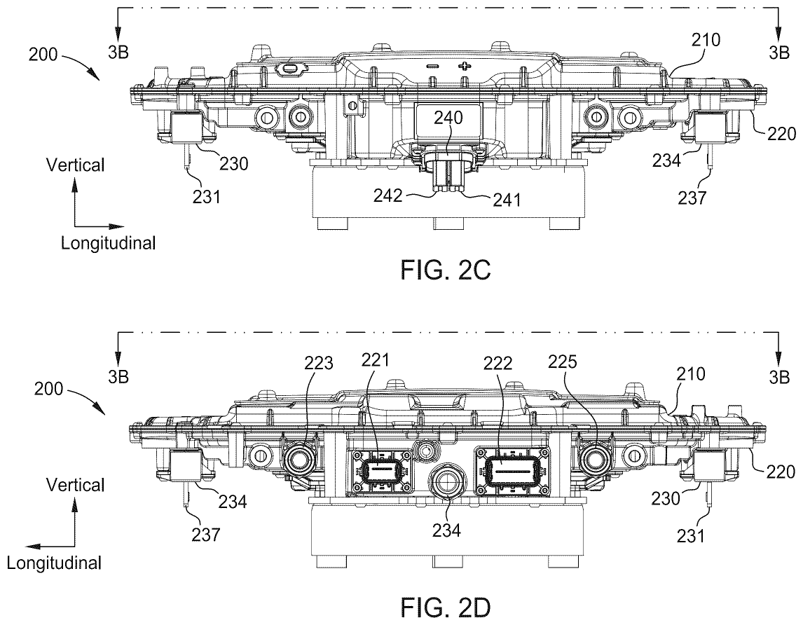

FIGS. 2A, 2B, 2C, 2D present top, bottom, front, and rear views of traction inverter system (TIS) 200 (respectively), in accordance with embodiments of the present disclosure.

In certain embodiments, a dual motor EDU for an electric vehicle may include, inter alia, two 3-phase AC electric motors, two gearboxes, and TIS 200 that contains power electronics (such as a dual power inverter module or DPIM, etc.). TIS 200 may include a capacitor module (such as a DC link capacitor, etc.), power inverter modules (PIMs), a cooling subsystem, one or more controller boards including one or more controllers, processors, supporting components, circuitry, connectors, etc. Additionally, an HV battery cable connector, electrical signal connectors, and cooling subsystem connectors are also provided.

FIGS. 2A and 2B present top and bottom views of TIS 200, in accordance with embodiments of the present disclosure.

TIS 200 includes cover 210 and housing 220, which form a sealed enclosure for the power electronics mounted within.

Cover 210 may be a metal casting, stamping, etc., that is formed as a single component. Cover 210 may conform closely to the dimensions of the power electronics contained within TIS 200. In other words, cover 210 may be contoured to minimize the volume within TIS 200.

Cover 210 may define a number of openings 212 to receive fasteners 214 that cooperate with threaded holes 226 in housing 220 to secure cover 210 to housing 220. Two openings 212 and two fasteners 214 are identified in FIGS. 2A, 2B. Cover 210 may also define a number of openings 216 to receive fasteners (not shown) that pass through bosses 228 in housing 220 to secure TIS 200 to the vehicle frame. Two openings 216 and two bosses 228 are identified in FIGS. 2A, 2B.

Housing 220 may be a metal casting that is formed as a single component.

Housing 220 includes a number of external connectors, such as electrical signal connector 221, electrical signal connector 222, cooling subsystem connectors 223, 224, 225, electric motor 1 busbar assembly 230, electric motor 2 busbar assembly 234, and HV battery cable connector 240. Generally, electrical signal connectors 221, 222 are pin-type connectors. Electric motor 1 busbar assembly 230 includes phase A terminal blade 231, phase B terminal blade 232, and phase C terminal blade 233. Similarly, electric motor 2 busbar assembly 234 includes phase A terminal blade 235, phase B terminal blade 236, and phase C terminal blade 237. HV battery cable connector 240 includes with positive terminal blade 241 and negative terminal blade 242.

Electric motor 1 busbar assembly 230 is connected to a respective socket on 3-phase AC electric motor 1, electric motor 2 busbar assembly 234 is connected to a respective socket on 3-phase AC electric motor 2, and HV battery cable connector 240 is connected to the battery via an HV battery cable.

Longitudinal and transverse axes for TIS 200, as well as section line 3A, are identified FIGS. 2A, 2B.

FIGS. 2C and 2D present front and rear views of TIS 200, in accordance with embodiments of the present disclosure.

Cover 210, housing 220, electric motor 1 busbar assembly 230 with phase A terminal blade 231, electric motor 2 busbar assembly 234 with phase A terminal blade 235, and HV battery cable connector 240 with positive terminal blade 241 and negative terminal blade 242 are identified in FIG. 2C.

Cover 210, housing 220, electrical signal connector 221, electrical signal connector 222, cooling subsystem connectors 223, 224, 225, electric motor 1 busbar assembly 230 with phase C terminal blade 233, electric motor 2 busbar assembly 234 with phase C terminal blade 237, and HV battery cable connector 240 with positive terminal blade 241 and negative terminal blade 242 are identified in FIG. 2D.

Longitudinal and vertical axes for TIS 200, as well as section line 3B, are also identified FIGS. 2C, 2D.

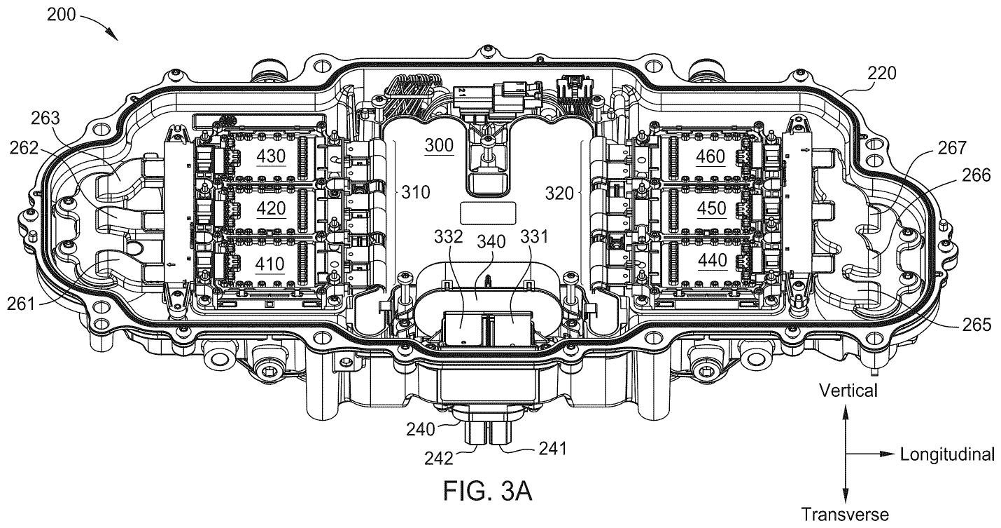

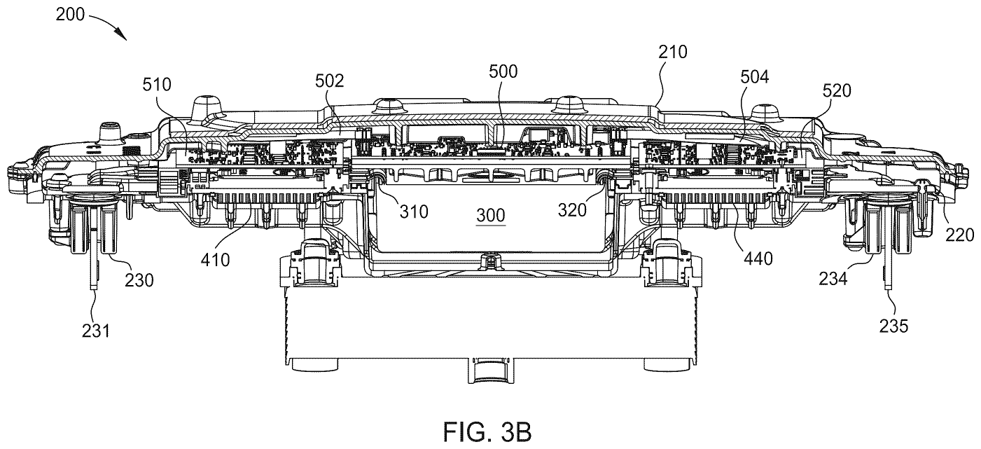

FIG. 3A presents a perspective sectional view through TIS 200, in accordance with embodiments of the present disclosure. The sectional plane for FIG. 3A is defined by the longitudinal and transverse axes. FIG. 3B presents a front sectional view through TIS 200, in accordance with embodiments of the present disclosure. The sectional plane for FIG. 3B is defined by the longitudinal and vertical axes.

TIS 200 includes, inter alia, capacitor module 300, PIMs 410, 420, 430 for motor 1, PIMs 440, 450, 460 for motor 2, main controller board 500, controller board 510 for motor 1, and controller board 520 for motor 2. In certain embodiments, controller board 510 and controller board 520 are gate driver printed circuit board assemblies (PCBAs). Capacitor module 300 is coupled to the input side of PIMs 410, 420, 430 using capacitor busbar contacts 310 that are laser welded to respective PIM busbar contacts. Capacitor module 300 is similarly coupled to the input side of PIMs 440, 450, 460 using capacitor busbar contacts 320 that are laser welded to respective PIM busbar contacts.

PIMs 410, 420, 430, each include an inverter to provide one phase of the 3-phase AC power to AC motor 1. The output side of PIM 410 is coupled to phase A terminal blade 231 of electric motor 1 busbar assembly 230 via power trace 261. The output side of PIM 420 is coupled to phase A terminal blade 232 of electric motor 1 busbar assembly 230 via power trace 262. The output side of PIM 430 is coupled to phase A terminal blade 233 of electric motor 1 busbar assembly 230 via power trace 263.

Similarly, PIMs 440, 450, 460, each include an inverter to provide one phase of the 3-phase AC power to AC motor 2. The output side of PIM 440 is coupled to phase A terminal blade 235 of electric motor 2 busbar assembly 234 via power trace 265. The output side of PIM 450 is coupled to phase A terminal blade 236 of electric motor 2 busbar assembly 234 via power trace 266. The output side of PIM 460 is coupled to phase A terminal blade 237 of electric motor 2 busbar assembly 234 via power trace 267.

The inverters may also function as converters to convert the AC power generated by the AC motor into DC power to recharge the battery during regeneration. Alternatively, PIMs 410, 420, 430, 440, 450, 460 may each include a separate converter for regeneration.

Capacitor module 300 includes a number of capacitors (such as 6, 8, 10, 12, 14, 16, 18, 20, etc.), positive terminal 331, negative terminal 332, and DC common mode choke 340. The positive terminal of each capacitor is connected to a positive capacitor busbar, and the negative terminal of each capacitor is connected to a negative capacitor busbar layer. The capacitors are coupled in parallel to the battery, and maintain a consistent voltage across the PIM inverters. More particularly, the capacitors stabilize the DC voltage received from the battery to limit fluctuations when the PIM inverters intermittently demand a large (or heavy) DC current. Positive terminal 331 is connected to the positive capacitor busbar and to positive terminal blade 241 of HV battery cable connector 240. Negative terminal 332 is connected to the negative capacitor busbar and to negative terminal blade 242 of HV battery cable connector 240. DC common mode choke 340 surrounds positive terminal 331 and negative terminal 332, and reduces the transmission of high frequencies to and from capacitor module 300.

Main controller board 500 and controller boards 510, 520 each include one or more controllers, processors, supporting components, circuitry, connectors, etc. Main controller board 500 is connected to electrical signal connectors 221, 222. Controller board 510 is connected to main controller board 500 via cable 502, and controller board 520 is connected to main controller board 500 via cable 504. Controller board 510 controls the AC power (AC voltage and current) provided to motor 1, while controller board 520 controls the AC power (AC voltage and current) provided to motor 2. Main controller board 500 controls the operations of controller boards 510, 520 in response to control signals received over the wires coupled to electrical signal connectors 221, 222.

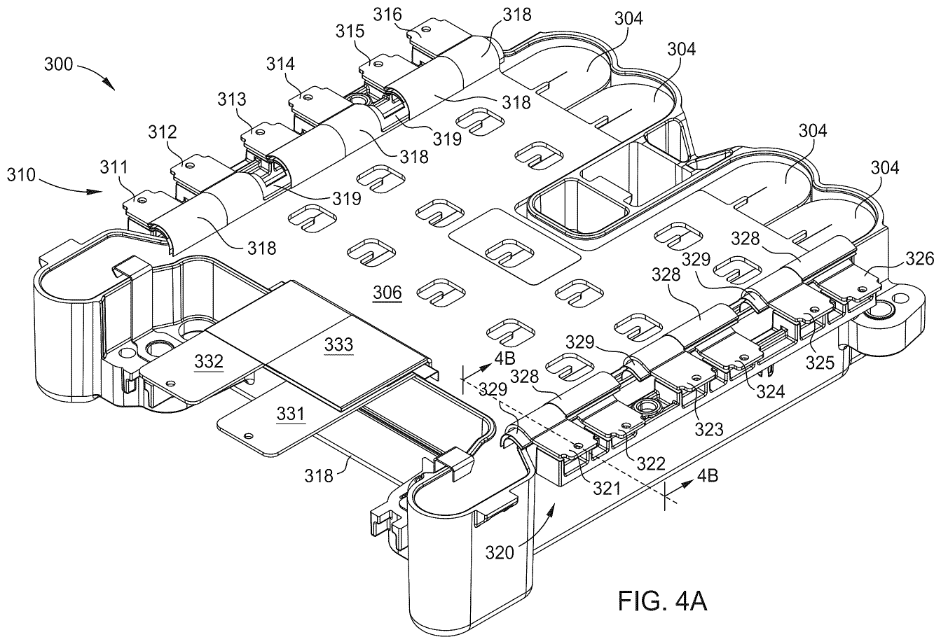

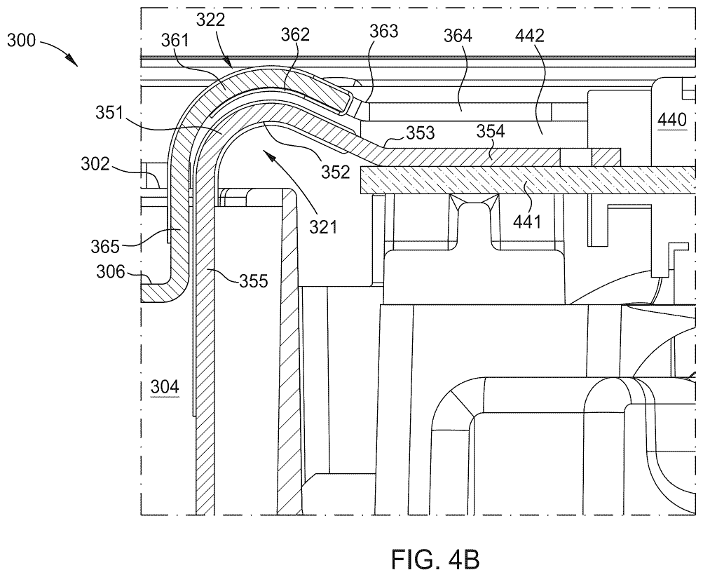

FIG. 4A presents a perspective view of an example capacitor module, in accordance with embodiments of the present disclosure. Section line 4B is identified.

Capacitor module 300 includes housing 302, upper cover (not depicted for clarity), capacitors 304, positive capacitor busbar layer 306, negative capacitor busbar layer (not visible under capacitors 304), capacitor busbar contacts 310, capacitor busbar contacts 320, positive terminal 331, and negative terminal 332. Positive terminal 331 is connected to positive capacitor busbar layer 306, and negative terminal 332 is connected to the negative capacitor busbar layer. Insulation 333 may be provided to isolate positive terminal 331 and negative terminal 332. Eighteen (18) capacitors 304 are depicted in FIG. 4A; other numbers of capacitors are also supported.

Capacitor busbar contacts 310 includes capacitor busbar contacts 311, 312, 313, 314, 315, 316. Capacitor busbar contacts 311, 313, 315 are coupled to the positive capacitor busbar layer 306, while capacitor busbar contacts 312, 314, 316 are coupled to negative capacitor busbar layer. Insulation 318, 319 may be provided for capacitor busbar contacts 311, 312, 313, 314, 315, 316.

Similarly, capacitor busbar contacts 320 includes capacitor busbar contacts 321, 322, 323, 324, 325, 326. Capacitor busbar contacts 321, 323, 325 are coupled to the negative capacitor busbar layer, while capacitor busbar contacts 322, 324, 326 are coupled to positive capacitor busbar layer 306. Insulation 328, 329 may be provided over capacitor busbar contacts 321, 322, 323, 324, 325, 326.

Generally, positive capacitor busbar layer 306 may be a sheet, flat surface, plane, area, region, etc., of conductive material, such as copper, that electrically couples the positive terminals of capacitors 304 to positive terminal 331, capacitor busbar contacts 311, 313, 315, and capacitor busbar contacts 322, 324, 326. Similarly, negative capacitor busbar layer (not visible) may be a sheet, flat surface, plane, area, region, etc. of conductive material, such as copper, that electrically couples the negative terminals of capacitors 304 to negative terminal 332, capacitor busbar contacts 312, 314, 316, and capacitor busbar contacts 321, 323, 325.

Each PIM 410, 420, 430, 440, 450, 460 includes a pair of PIM busbar contacts. Capacitor module 300 is coupled to PIMs 410, 420, 430 using pairs of capacitor busbar contacts 310, and to PIMs 440, 450, 460 using pairs of capacitor busbar contacts 320.

More particularly, capacitor busbar contacts 311, 312 are coupled to the busbar contacts of PIM 410, capacitor busbar contacts 313, 314 are coupled to the busbar contacts of PIM 420, and capacitor busbar contacts 315, 316 are coupled to the busbar contacts of PIM 430. Similarly, capacitor busbar contacts 321, 322 are coupled to the busbar contacts of PIM 440, capacitor busbar contacts 323, 324 are coupled to the busbar contacts of PIM 450, and capacitor busbar contacts 325, 326 are coupled to the busbar contacts of PIM 460

Capacitor busbar contacts 310, 320 and the PIM busbar contacts are configured to attach to one another at a respective portion of each contact that are generally flat, rectangular conductive segments. The busbar contacts may be formed from a conductive material, such as copper, aluminum, etc. Capacitor busbar contacts 310, 320 extend away from housing 302 of capacitor module 300, and are attached to the PIM busbar contacts using certain welding techniques, such as laser welding.

For example, it can be beneficial to perform laser welding such that capacitor busbar contacts 310, 320 abut (or contact) the respective PIM busbar contacts without an air gap, or with a reduced air gap, which may reduce the strength of the laser weld. For instance, part tolerances in capacitor module 300 and PIMs 410, 420, 430, 440, 450, 460 may cause the formation of such an air gap during laser welding with a concomitant reduction in the strength of the laser weld. Other welding techniques may also suffer from similar issues.

FIG. 4B presents a partial sectional view through capacitor module 300, in accordance with embodiments of the present disclosure.

Housing 302, one capacitor 304, positive capacitor busbar layer 306, and capacitor busbar contacts 321, 322 of capacitor module 300 are depicted. PIM 440 includes a pair of PIM busbar contacts 441, 442, which are attached to capacitor busbar contacts 321, 322, respectively. PIM busbar contacts 441, 442 each have a flat shape.

Generally, each capacitor busbar contact 310, 320 has a flexible portion and a contact portion that is configured to be laser welded to a respective PIM busbar contact. The flexible portion and the contact portion are disposed outside of housing 302. The flexible portion is configured to bend to reduce or close the air gap between the contact portion and respective PIM busbar contact when the contact portion is clamped or pressed to the respective PIM busbar contact (e.g., prior to laser welding).

Capacitor busbar contact 321 and capacitor busbar contact 322 will now be described as an exemplary pair of capacitor busbar contacts.

Capacitor busbar contact 321 includes a flexible portion 351 and contact portion 354. Flexible portion 351 has a curved shape with bend 352 and bend 353, and contact portion 354 has a flat shape. Flexible portion 351 and contact portion 354 have many advantageous characteristics. Bend 352 has an arc that is greater than 90°, while bend 353 has an arc that is less than 90°. Bend 352 faces toward housing 302, while bend 353 faces away from housing 302. In certain embodiments, the combined arc of bend 352 and bend 353 is approximately 90 degrees. In some certain embodiments, bend 352 has an arc of approximately 135° and bend 353 has an arc of approximately −45°. The combination of bend 352 and bend 353 allows for movement of contact area 354 in a substantially vertical direction without pulling the leg portion 355 out of a vertical orientation.

Due to the arcs and orientations of bends 352, 353, clamping capacitor busbar contact 321 to PIM busbar contact 441 causes flexible portion 351 to flex so that contact portion 354 lies flat against PIM busbar contact 441, thereby improving laser weld quality (e.g., by increasing the strength of the laser weld). Capacitor busbar contact 321 also includes leg portion 355 that is coupled to the negative capacitor busbar layer (not visible).

Similarly, capacitor busbar contact 322 includes a flexible portion 361 and contact portion 364. Flexible portion 361 has a curved shape with bend 362 and bend 363, and contact portion 364 has a flat shape. Flexible portion 361 and contact portion 364 also have many advantageous characteristics. Bend 362 has an arc that is greater than 90°, while bend 363 has an arc that is less than 90°. Bend 363 faces toward housing 302, while bend 362 faces away from housing 302. In certain embodiments, the combined arc of bend 362 and bend 363 is approximately 90 degrees. In some certain embodiments, bend 362 has an arc of approximately 135° and bend 363 has an arc of approximately −45°. The radius of the arc of bend 362 may be larger than the radius of the arc of bend 352, and bend 362 may be disposed at a higher elevation with respect to housing 302 than bend 352. Similarly, bend 363 may be disposed at a higher elevation with respect to housing 302 than bend 353. The combination of bend 362 and bend 363 allows for movement of the contact area 364 in a substantially vertical direction without pulling the leg portion 365 out of a vertical orientation.

Due to the arcs and orientations of bends 362, 363, clamping capacitor busbar contact 322 to PIM busbar contact 442 causes flexible portion 361 to flex so that contact portion 364 lies flat against PIM busbar contact 442, thereby improving laser weld quality. Capacitor busbar contact 322 also includes leg portion 365 that is coupled to positive capacitor busbar layer 306.

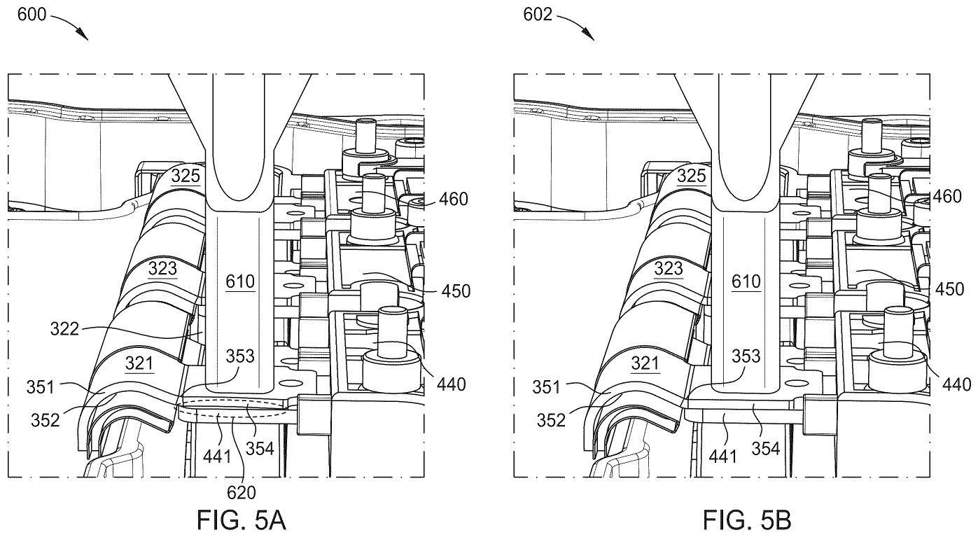

FIGS. 5A, 5B present a clamping process prior to laser welding for capacitor module 300 and PIM 440, in accordance with embodiments of the present disclosure.

Illustration 600 depicts capacitor busbar contacts 321, 322, 323, 325 (capacitor busbar contacts 324, 326 are not visible), PIMs 440, 450, 460, and clamp 610. Flexible portion 351 (with bends 352, 353) and contact portion 354 of capacitor busbar contact 321, as well as PIM busbar contact 441, are identified.

Generally, a force may be applied from above to the upper surface of each contact portion (e.g., contact portion 354) to reduce or close the air gap (e.g., air gap 620) prior to attaching the capacitor busbar contact (e.g., capacitor busbar contact 321) to the PIM busbar contact (e.g., PIM busbar contact 441). Reducing or closing the air gap improves the quality of certain types of attachment techniques, such as riveting, soldering, welding, etc. In certain embodiments, each capacitor busbar contact (e.g., capacitor busbar contact 321) may be laser welded to the respective PIM busbar contact (e.g., PIM busbar contact 441), and a clamp (e.g., clamp 610) may be used to apply the force to the upper surface of the contact portion (e.g., contact portion 354) prior to laser welding.

As depicted in illustration 600, clamp 610 has been positioned against the upper surface of contact portion 354, but no clamping pressure has been applied. Due to the various part tolerances, air gap 620 may be present between the lower surface of contact portion 354 and the upper surface of PIM busbar contact 441, as depicted.

As depicted in illustration 602, clamp 610 is applying a clamping force between 100 N and 300 N (such as 200 N) to contact portion 354 prior to laser welding capacitor busbar contact 321 to PIM busbar contact 441. Air gap 620 has been reduced or closed prior to laser welding, which improves laser weld quality (e.g., by increasing the strength of the laser weld).

Generally, contact portion 354 and PIM busbar contact 441 contact one another in two dimensions. A contact surface may define the extent to which the lower surface of contact portion 354 touches, abuts, contacts, etc. the upper surface of PIM busbar contact 441. The maximum contact surface is governed by the dimensions and arrangement of the lower surface of contact portion 354 and the upper surface of PIM busbar contact 441. When the contact surface is the maximum contact surface, contact portion 354 and PIM busbar contact 441 are in full contact, and no air gap exists between contact portion 354 and PIM busbar contact 441. When the contact surface is zero, contact portion 354 and PIM busbar contact 441 are not in contact, and an air gap exists between contact portion 354 and PIM busbar contact 441. When the contact surface is between the maximum contact surface and zero, contact portion 354 and PIM busbar contact 441 are in partial contact, and an air gap exists between contact portion 354 and PIM busbar contact 441.

In one example, contact portion 354 and PIM busbar contact 441 are not in contact before the force is applied to contact portion 354. In this example, the force applied to contact portion 354 reduces (and improves) the air gap between contact portion 354 and PIM busbar contact 441, resulting in partial contact or full contact between contact portion 354 and PIM busbar contact 441. In another example, contact portion 354 and PIM busbar contact 441 are in partial contact before the force is applied to contact portion 354. In this example, the force applied to contact portion 354 reduces (and improves) the air gap between contact portion 354 and PIM busbar contact 441, resulting in greater partial contact or full contact between contact portion 354 and PIM busbar contact 441. In other words, applying the force to contact portion 354 may create full contact between contact portion 354 and PIM busbar contact 441, or may improve the air gap (but not reduce the air gap completely), such as when contact portion 354 is brought closer to PIM busbar contact 441 to create partial contact, or when the contact surface is increased to create greater partial contact.

The many features and advantages of the disclosure are apparent from the detailed specification, and, thus, it is intended by the appended claims to cover all such features and advantages of the disclosure which fall within the scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

What is claimed is:

1. A capacitor module, comprising:
a housing;
a plurality of capacitors; and
a plurality of capacitor busbar contacts coupled to the capacitors, each capacitor busbar contact including:
a flexible portion, and
a contact portion configured to be attached to a respective power inverter module (PIM) busbar contact,
wherein the flexible portion and the contact portion are disposed outside the housing, and
wherein the flexible portion is configured to bend under a force to reduce an air gap between the contact portion and respective PIM busbar contact prior to attaching the contact portion to the respective PIM busbar contact.

2. The capacitor module of claim 1, wherein the contact portion is laser welded to the respective PIM busbar contact, and a clamp applies the force to the flexible portion prior to laser welding.

3. The capacitor module of claim 1, wherein the flexible portion has a curved shape with a first bend and a second bend and the contact portion has a flat shape.

4. The capacitor module of claim 3, wherein the first bend has an arc that is greater than 90°, and the second bend has an arc that is less than 90°.

5. The capacitor module of claim 3, further comprising:
a first busbar including:
a first busbar layer coupled to a first terminal of each capacitor, and
a plurality of first busbar contacts coupled to the first busbar layer; and
a second busbar including:
a second busbar layer coupled to a second terminal of each capacitor, and
a plurality of second busbar contacts coupled to the second busbar layer,
wherein the plurality of capacitor busbar contacts comprise the plurality of first busbar contacts and the plurality of second busbar contacts.

6. The capacitor module of claim 5, wherein:
each first busbar contact includes a first leg portion, a first flexible portion, and a first contact portion;
the first leg portion is coupled to the first busbar layer;
the first flexible portion extends from the first leg portion; and
the first contact portion extends from the first flexible portion.

7. The capacitor module of claim 6, wherein:
each second busbar contact includes a second leg portion, a second flexible portion, and a second contact portion;
the second leg portion is coupled to the second busbar layer;
the second flexible portion extends from the second leg portion; and
the second contact portion extends from the second flexible portion.

8. The capacitor module of claim 5, further comprising:
a first high voltage (HV) cable contact coupled to the first busbar layer; and
a second HV cable contact coupled to the second busbar layer.

9. The capacitor module of claim 5, wherein:
the plurality of capacitor busbar contacts are arranged as pairs of capacitor busbar contacts;
each pair of capacitor busbar contacts includes one first busbar contact and one second busbar contact; and
each pair of capacitor busbar contacts is configured to be attached to a pair of busbar contacts on a respective PIM.

10. The capacitor module of claim 9, wherein the plurality of capacitor busbar contacts are arranged as six pairs of capacitor busbar contacts, and each pair of capacitor busbar contacts is configured to be attached to a pair of busbar contacts on one of six PIMs.

11. The capacitor module of claim 9, wherein the plurality of capacitor busbar contacts are arranged as three pairs of capacitor busbar contacts, and each pair of capacitor busbar contacts is configured to be attached to a pair of busbar contacts on one of three PIMs.

12. The capacitor module of claim 9, wherein each pair of capacitor busbar contacts includes insulation disposed on the flexible portion of the first busbar contact and the flexible portion of the second busbar contact.

13. A method, comprising:
providing a capacitor module and a plurality of power inverter modules (PIMs), the capacitor module including capacitors and capacitor busbar contacts, each capacitor busbar contact including a flexible portion and a contact portion, each PIM including PIM busbar contacts;
for each capacitor busbar contact:
applying a force to the contact portion to reduce an air gap between the contact portion and a respective PIM busbar contact; and
attaching the contact portion to the respective PIM busbar contact.

14. The method of claim 13, wherein the force is applied by a clamp, and the contact portion is laser welded to the respective PIM busbar contact.

15. The method of claim 13, wherein the flexible portion has a curved shape with a first bend and a second bend, the contact portion has a flat shape, and each PIM busbar contact has a flat shape.

16. The method of claim 15, wherein the first bend has an arc that is greater than 90°, and the second bend has an arc that is less than 90°.

17. The method of claim 13, wherein the capacitor module further comprises:
a first busbar including:
a first busbar layer coupled to a first terminal of each capacitor, and
a plurality of first busbar contacts coupled to the first busbar layer; and
a second busbar including:
a second busbar layer coupled to a second terminal of each capacitor, and
a plurality of second busbar contacts coupled to the second busbar layer,
wherein the capacitor busbar contacts comprise the plurality of first busbar contacts and the plurality of second busbar contacts.

18. A traction inverter system for an electric vehicle, comprising:
a plurality of power inverter modules (PIMs), each PIM including an inverter and a pair of busbar contacts; and
a capacitor module, including:
a housing;
a plurality of capacitors; and
a plurality of capacitor busbar contacts coupled to the capacitors, each capacitor busbar contact including:
a flexible portion, and
a contact portion attached to a respective PIM busbar contact,
wherein the flexible portion and the contact portion are disposed outside the housing, and
wherein the capacitor busbar contacts are arranged as pairs of capacitor busbar contacts, and each pair of capacitor busbar contacts is attached to the pair of busbar contacts on one of the PIMs.

19. The traction inverter system of claim 18, wherein the contact portion is laser welded to the respective PIM busbar contact.

20. The traction inverter system of claim 18, wherein the flexible portion has a curved shape with a first bend and a second bend, the contact portion has a flat shape, and each PIM busbar contact has a flat shape.

21. The traction inverter system of claim 20, wherein the first bend has an arc that is greater than 90°, and the second bend has an arc that is less than 90°.

22. The traction inverter system of claim 18 wherein the capacitor module further comprises:
a first busbar including:
a first busbar layer coupled to a first terminal of each capacitor, and
a plurality of first busbar contacts coupled to the first busbar layer; and
a second busbar including:
a second busbar layer coupled to a second terminal of each capacitor, and
a plurality of second busbar contacts coupled to the second busbar layer,
wherein the plurality of capacitor busbar contacts comprise the plurality of first busbar contacts and the plurality of second busbar contacts.

23. The traction inverter system of claim 22, wherein:
each first busbar contact includes a first leg portion, a first flexible portion, and a first contact portion;
the first leg portion is coupled to the first busbar layer;
the first flexible portion extends from the first leg portion;
the first contact portion extends from the first flexible portion.
each second busbar contact includes a second leg portion, a second flexible portion, and a second contact portion;
the second leg portion is coupled to the second busbar layer;
the second flexible portion extends from the second leg portion; and
the second contact portion extends from the second flexible portion.
